(19) United States
(12) Patent Application Publication
(10) Pub. No.: US 2014/0159181 A1
(43) Pub. Date: Jun. 12, 2014

(54) GRAPHENE-NANOPARTICLE STRUCTURE AND METHOD OF MANUFACTURING THE SAME

(71) Applicant: SAMSUNG ELECTRONICS CO., LTD., Suwon-si (KR)

(72) Inventors: Sung-min KIM, Seoul (KR); Dae-Jun KANG, Suwon-si (KR); Seung-nam CHA, Seoul (KR); Muhammad Imran SHAKIR, Suwon-si (KR); Young-jun PARK, Suwon-si (KR)

(73) Assignee: SAMSUNG ELECTRONICS CO., LTD., Suwon-si (KR)

(21) Appl. No.: 14/102,965

(22) Filed: Dec. 11, 2013

(30) Foreign Application Priority Data
Dec. 11, 2012 (KR) 10-2012-0143824

(51) Int. Cl. B01J 35/00; H01L 31/028; B01J 23/52

(52) U.S. Cl. CPC B01J 35/004; B01J 23/52; H01L 31/028
USPC 257/431; 502/180; 502/184; 502/182; 502/159

(57) ABSTRACT

A graphene-nanoparticle structure includes a substrate, a graphene layer disposed on the substrate and a nanoparticle layer disposed on the graphene layer. The graphene-nanoparticle structure may be formed by alternately laminating the graphene layer and the nanoparticle layer and may play the role of a multifunctional film capable of realizing various functions according to the number of laminated layers and the selected material of the nanoparticles.

### CROSS-REFERENCE TO RELATED APPLICATION

This application claims from Korean Patent Application No. 10-2012-0143824, filed Dec. 11, 2012, in the Korean Intellectual Property Office, the disclosure of which is incorporated by reference herein in its entirety.

### BACKGROUND

1. Field

The present disclosure relates to a graphene-nanoparticle structure and a method of manufacturing the same.

2. Description of the Related Art

Graphene is thin film material in which carbon atoms are arranged two-dimensionally. Electric charges therein function as zero effective mass particles, and thus graphene has very high electric conductivity. Graphene has also been known to have high thermal conductivity and elasticity, as well as very high electrical conductivity. Accordingly, graphene materials have drawn a lot of attention in diverse fields, and studies on the electrical and physical characteristics of graphene have been attempted

### SUMMARY

Exemplary embodiments relate to a graphene-nanoparticle structure and a method of manufacturing the same.

According to an aspect of an exemplary embodiment, there is provided a graphene-nanoparticle structure including a substrate, a first graphene layer disposed on the substrate, and a first nanoparticle layer disposed on the first graphene layer.

At least one second graphene layer and at least one second nanoparticle layer may be alternately disposed on the first nanoparticle layer.

The first and second graphene layers may be surface treated to have positive electric charges.

The first nanoparticle layer may be formed of metals, metal oxides, semiconductors, or polymer materials.

According to an aspect of another exemplary embodiment, there is provided a photocatalytic structure includes a substrate and a photocatalytic layer including at least one graphene layer and at least one nanoparticle layer alternately disposed on the substrate.

The graphene layer may be surface treated to have positive electric charges.

A plurality of nanoparticles may be configured to provide a peak efficiency of optical absorption in a band of visible light. The plurality of nanoparticles may be, gold nanoparticles.

According to an aspect of another exemplary embodiment, there is provided a photoelectric device including a substrate, a photoactive layer including at least one graphene layer and at least one nanoparticle layer formed by using a plurality of nanoparticles disposed on the graphene layer, and an electrode unit configured to connect photoelectrically converted electrical energy in the photoactive layer to an external load.

According to an aspect of another embodiment, there is provided a method of manufacturing a graphene-nanoparticle structure including: forming a first graphene layer on a substrate; and forming a first nanoparticle layer on the graphene layer.

The forming of the first graphene layer may include synthesizing graphene on a first substrate having a metal catalyst layer formed thereon by using a chemical vapor deposition method and transferring the synthesized graphene onto a second substrate.

The substrate having the metal catalyst layer formed thereon may be a copper (Cu) foil.

The method may further include coating polymethyl methacrylate (PMMA) on the synthesized graphene and removing the copper foil before transferring the synthesized graphene onto the second substrate.

The substrate may be a polyethylene terephthalate (PET) substrate.

The method may further include surface treating the first graphene layer to impart positive electric charges onto the first graphene layer.

The forming of the first nanoparticle layer may include forming an aqueous solution containing a plurality of nanoparticles, and aligning the plurality of nanoparticles contained in the aqueous solution onto the graphene layer by the Langmuir-Blodgett (LB) method.

The plurality of nanoparticles may be formed of metals, metal oxides, semiconductors, or polymer materials.

The method of manufacturing the graphene-nanoparticle structure may additionally include forming a second graphene layer on the first nanoparticle layer, and forming a second nanoparticle layer on the second graphene layer.

### BRIEF DESCRIPTION OF THE DRAWINGS

These and/or other aspects will become apparent and more readily appreciated from the following description of embodiments, taken in conjunction with the accompanying drawings of which:

FIG. 1 is a structural view schematically illustrating a graphene-nanoparticle structure according to an exemplary embodiment;

FIG. 2 is a structural view schematically illustrating a photocatalytic structure according to an exemplary embodiment;

FIG. 3 is a graph illustrating an absorption wavelength band as a function of the number of laminated layers that form a photocatalytic layer in the photocatalytic structure in FIG. 2;

FIG. 4 is a graph illustrating photocatalysis as a function of the number of laminated layers that form a photocatalytic layer in the photocatalytic structure in FIGS. 2; and

FIGS. 5A to 5L are views describing a method of manufacturing a graphene-nanoparticle structure according to exemplary embodiments.

### DETAILED DESCRIPTION

Reference will now be made in detail to embodiments, examples of which are illustrated in the accompanying drawings, wherein like reference numerals refer to the like elements throughout. In this regard, the exemplary embodiments may have different forms and should not be construed as being limited to the descriptions set forth herein. Accordingly, the exemplary embodiments are merely described below, by referring to the figures, to explain aspects of the present disclosure.

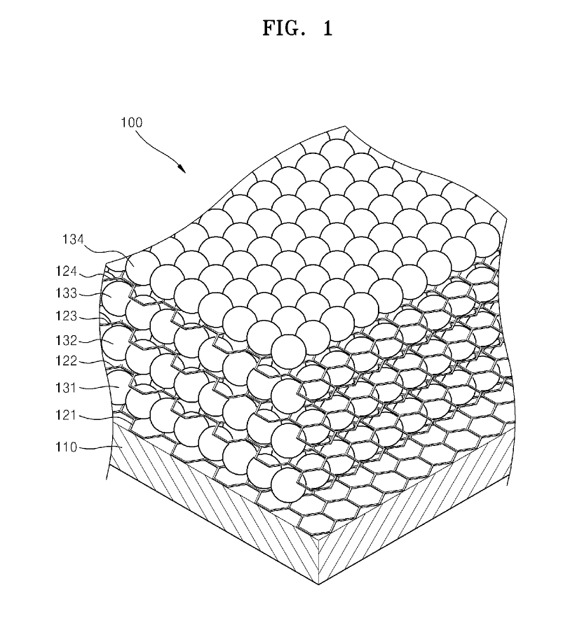

FIG. 1 is a structural view schematically illustrating a graphene-nanoparticle structure 100 according an exemplary embodiment.

Referring to FIG. 1, a graphene-nanoparticle structure 100 includes a substrate 110, a first graphene layer 121 disposed on the substrate 110, and a first nanoparticle layer 131 disposed on the first graphene layer 121. Further, at least one or more second graphene layers 122, 123, and 124, and at least one or more second nanoparticle layers 132, 133, and 134 are alternately disposed on the first nanoparticle layer 131, and the number of layers alternately disposed is not limited to the number of layers illustrated in the drawing.

The substrate 110 may be a polyethylene terephthalate (PET) substrate, although other insulating substrates may be formed using various materials.

The first graphene layer 121 and the second graphene layers 122, 123, and 124 are formed using graphene materials. Although the first graphene layer 121 and the second graphene layers 122, 123, and 124 are shown in FIG. 1 as being in the form of a single sheet, this is illustrative only, and the first graphene layer 121 and the second graphene layers 122, 123, and 124 may comprise a plurality of graphene sheets. The first graphene layer 121 and the second graphene layers 122, 123, and 124 may be surface treated so as to have positive electric charges.

The first nanoparticle layer 131 and the second nanoparticle layers 132, 133, and 134 may be formed using metals, metal oxides, semiconductors, or polymer materials. Although the first nanoparticle layer 131 and the second nanoparticle layers 132, 133, and 134 are shown in FIG. 1 in the form of a single layer film including a plurality of nanoparticles having the same size, this is illustrative only, and the first nanoparticle layer 131 and the second nanoparticle layers 132, 133, and 134 may be in the form of a multilayer film which may include nanoparticles having different sizes.

The above-mentioned graphene-nanoparticle structure 100 facilitates the movement of electric charges on its boundary surface, and reduces the coupling of electrons and holes via the laminated structure including a positively charged graphene layer and a negatively charged nanoparticle layer. Accordingly, the graphene-nanoparticle structure 100 plays the role of a multifunctional film that is capable of realizing various functions according to the material selection of zero dimensional nanoparticles coupled to the graphene material. For instance, the graphene-nanoparticle structure 100 may be applied to photoelectric devices such as fuel cells or light collection devices, photocatalysts, and supercapacitors.

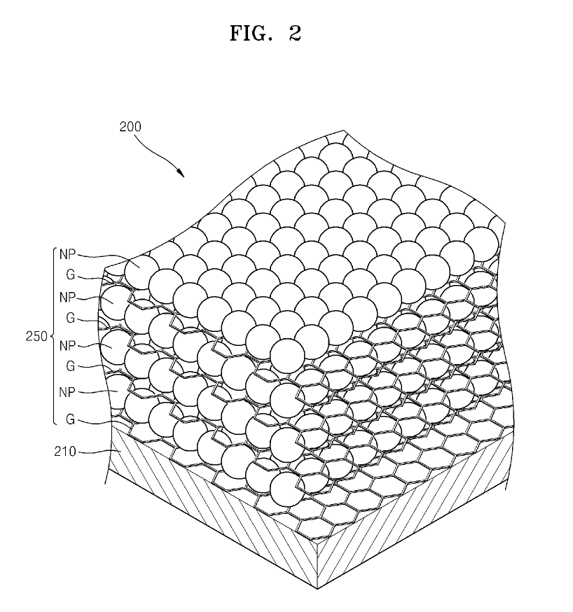

FIG. 2 is a structural view schematically illustrating a photocatalytic structure 200 according to an exemplary embodiment.

Referring to FIG. 2, the photocatalytic structure 200 includes a substrate 210 and a photocatalytic layer 250 disposed on the substrate 210. The photocatalytic layer 250 includes at least one graphene layer G, and a nanoparticle layer NP which is disposed on a graphene layer G and formed from a plurality of nanoparticles. As illustrated in FIG. 2, multiple graphene layers G and multiple nanoparticle layers NP may be formed into a structure in which they are alternately disposed.

The photocatalytic layer 250 carries out the function of a photocatalyst, and the number of layers in the photocatalytic layer 250 is not limited to the number of the layers illustrated in the drawing, and may be greatly varied. If the photocatalyst receives light having energy that is not less than the band gap energy, the photocatalyst plays the role of exciting electrons from the valence band to the conduction band to form electrons in the conduction band and holes in the valence band, and diffuses the formed electrons and holes onto the surface of the photocatalyst, thereby allowing the electrons and holes to participate in, for example, an oxidation and reduction reaction. For instance, such a photocatalyst may be used to produce hydrogen in a next-generation alternative energy source by directly photolyzing water using solar energy, may be used to sterilize germs and bacteria, may be used to decompose volatile organic compounds (VOCs), varieties of malodors, wastewater, recalcitrant contaminants and environmental hormones, and may be used to decompose organic pollutants such as TBO (Toluidine Blue O). Therefore, photocatalyst technology using solar energy alone at room temperature is of great interest as being a powerful solution for hydrogen production, environmental cleanup, and environmental problems. The photocatalytic structure layer 200 has a structure which is well-suited to light exposure and which is high in light absorptivity.

A graphene layer G is formed by using a graphene material and may be surface treated such that the graphene layer G has positive electric charges. Although the graphene layer G is illustrated in FIG. 2 as being a single graphene sheet, graphene layer G is not limited thereto.

A plurality of nanoparticles forming a nanoparticle layer NP may be selected such that their materials and sizes provide for a peak light absorption efficiency appearing in the band of visible light. As an example, the plurality of nanoparticles may be formed of gold or other noble metal.

The number of laminated layers in the photocatalytic layer 250 is not limited to the number of the layers shown in FIG. 2, and it may be greatly varied. Further, although the graphene layer G and the nanoparticle layer NP are illustrated in FIG. 2 as having the same number of layers, in photocatalytic structure 200, there may be a different number of graphene layers G and nanoparticle layers NP.

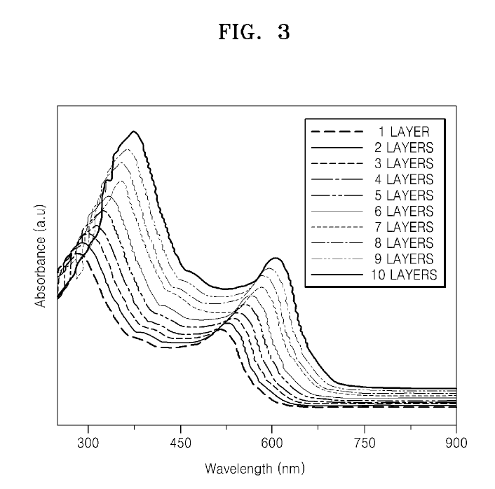

FIG. 3 is a graph illustrating an absorption wavelength band as a function of the total number of laminated layers forming the photocatalytic layer in the photocatalytic structure 200 in FIG. 2.

Referring to the graph, as the number of laminated layers increases, absorptivity increases, and the peak absorptivity wavelength band shifts to the right. Although not wishing to be bound by theory, it is surmised that such a phenomenon occurs as a result of the surface plasmon resonance phenomenon being controlled by the number of laminated layers. The surface plasmon resonance phenomenon occurs via an interaction between free electrons on the metal surface and incident light, and since the number of interfaces in which the plasmon resonance occurs increases with the number of laminated layers, the plasmon coupling extent varies.

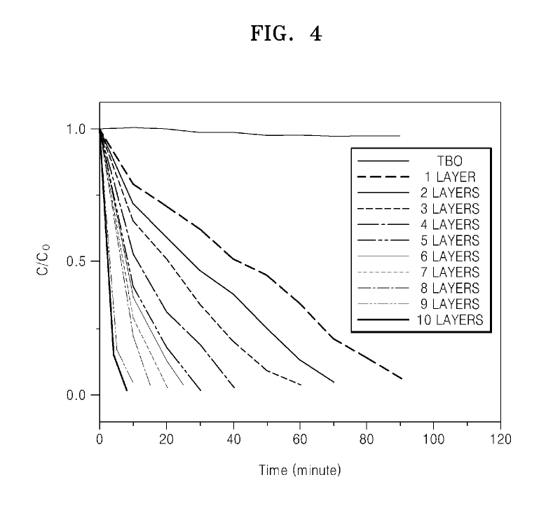

FIG. 4 is a graph illustrating photocatalysis as a function of the number of laminated layers that form photocatalytic layer 250 in the photocatalytic structure 200 of FIG. 2.

The graph shows the variation of TBO (Toluidine Blue O) concentration with respect to time exposed to a 300 W xenon (Xe) lamp. The graph shows the ratio C/C₀, which is the concentration of TBO over the initial concentration C₀ as a function of time. Referring to the graph, it can be seen that decomposition of TBO is conducted more quickly as the number of laminated layers increases.

The above-mentioned photocatalytic structure 200 may have a structure in which a graphene layer G and a nanoparticle layer NP are alternately laminated, and thus controlling the number of laminated layers may serve to control the light absorptivity, the wavelength band of light absorption, and photocatalysis. The photocatalytic structure 200 may be formed such that it covers a large area on the substrate and may perform photocatalysis more smoothly because the area exposed to light is large, and can be completely recovered following photocatalytic operation. For example, if the photocatalyst is in the form of powder and is settled down on the bottom of a reactor, the area exposed to light is small.

The graphene-nanoparticle structure 100 of FIG. 1 may also be used as a photoactive layer in a photoelectric device. A photoelectric device is a device that generates electrical signals in response to light, such as visible light, infrared light, ultraviolet light, and other types of light. The photoelectric device may be used as a device for detecting information included in the light or may be used as a battery (a solar battery) that collects light and produces electric power according to the properties of the incident light. The photoelectric device may include, for example, a photoactive layer formed from the graphene-nanoparticle structure 100, and an electrode unit connecting electrical energy which has been photoelectrically converted in the photoactive layer to an external load.

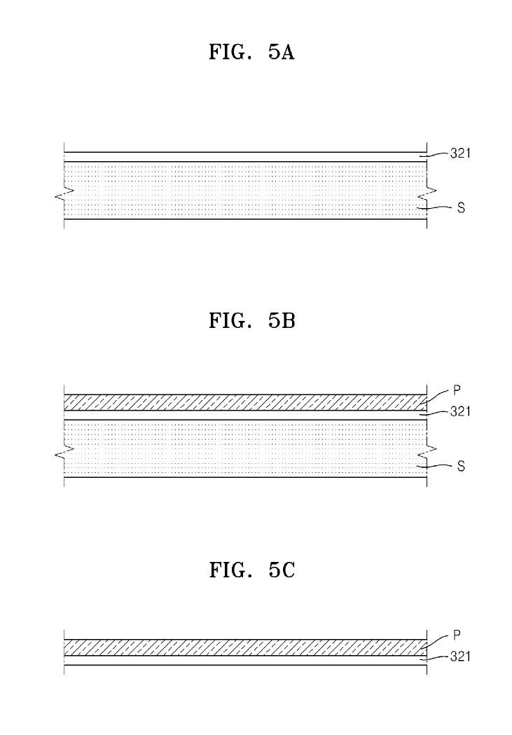

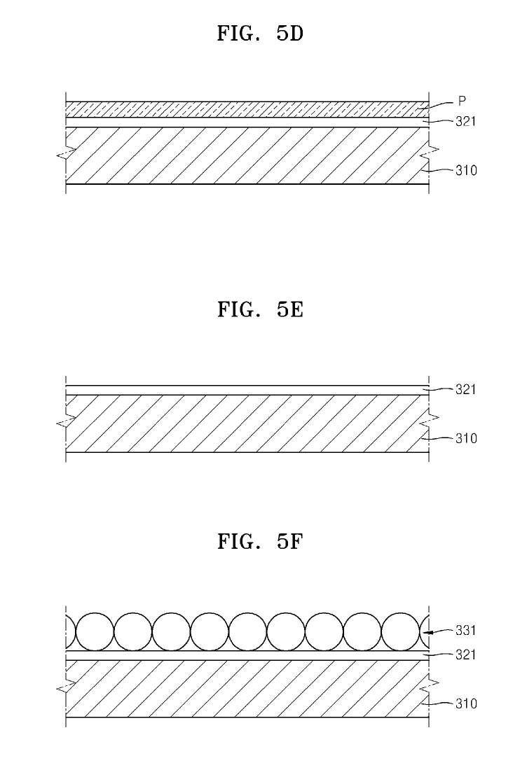

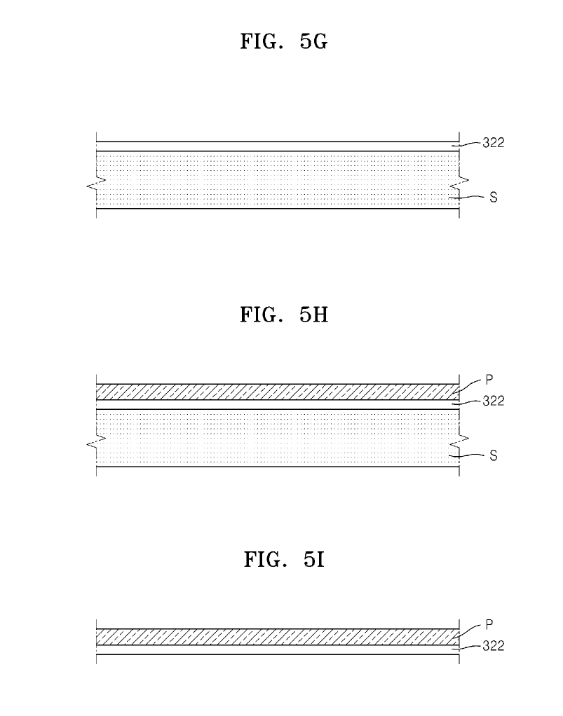

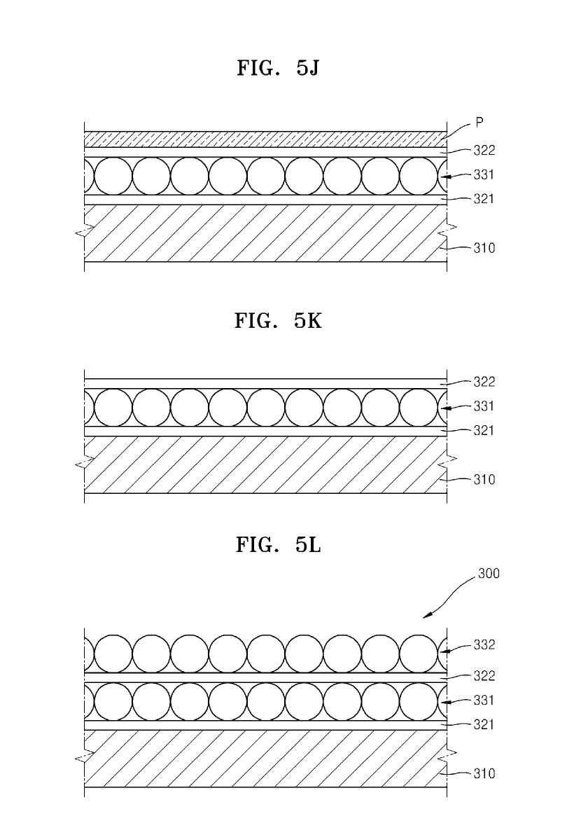

FIGS. 5A to 5L are views illustrating a method of manufacturing a graphene-nanoparticle structure according to exemplary embodiments.

A method of manufacturing a graphene-nanoparticle structure may include forming a graphene layer on a substrate and forming a nanoparticle layer on the graphene layer. Further, the method of manufacturing the graphene-nanoparticle structure may additionally include forming another graphene layer on the nanoparticle layer.

Exemplary processes will be disclosed as follows, referring to the drawings.

Referring to FIG. 5A, a graphene layer 321 may be formed by synthesizing graphene on a substrate S having a metal catalyst layer using chemical vapor deposition.

For instance, the substrate S having the metal catalyst layer may be prepared by depositing a metal catalyst such as nickel (Ni), copper (Cu), aluminum (Al), iron (Fe) or others onto the surface of a silicon substrate using sputtering equipment, electron beam evaporator, or other equipment. Next, a metal catalyst layer-formed substrate S and gases including carbon, such as CH₄, C₂H₂, C₂H₄, CO, and others are put into a reactor for thermal chemical vapor deposition or Inductive Coupled Plasma Chemical Vapor Deposition (ICP-CVD), and the reactor is heated such that carbon is absorbed into the metal catalyst layer. Subsequently, graphene is grown by a method of rapidly cooling the reactor and separating carbon from the metal catalyst layer to crystallize the separated carbon.

Foil formed from metal may be used as the substrate S having the metal catalyst layer. For example, copper foil may be used as the substrate S.

Next, as illustrated in FIG. 5B, a protection layer P is coated on the graphene layer 321. The protection layer P may be formed, for example, by spin-coating polymethyl methacrylate (PMMA).

Then, when the substrate S having the metal catalyst layer is removed from the structure of FIG. 5B by methods such as etching, the structure of FIG. 5C is formed. When copper foil is used as the substrate S having the metal catalyst layer, the copper foil may be etched by a wet process using, for example, ferrous chloride (FeCl₂) or ammonium persulfate ((NH₄)₂S₂O₈) as an etchant.

The structure of FIG. 5C may be cleaned using deionized water. The protection layer P plays the role of supporting the graphene layer 321 when transferring the graphene layer 321 to a required position. Thereafter, the protection layer P is removed after transferring the graphene layer 321 to the required position.

Namely, as illustrated in FIG. 5D, the structure of FIG. 5C is transferred onto a substrate 310, and the protection layer P is subsequently removed such that the graphene layer 321 is formed on the substrate 310 as illustrated in FIG. 5E. For example, a wet etching process may be used to remove the protection layer P.

Various types of insulating substrates other than a polyethylene terephthalate (PET) substrate may be used as the substrate 310. The method of manufacturing the graphene-nanoparticle structure additionally may include ultrasonically cleaning the substrate 310 before transferring the graphene layer 321 onto the substrate 310. For example, the substrate 310 may be sequentially cleaned by acetone, potassium hydroxide-dissolved ethanol, and distilled water. Further, the surface of the graphene layer 321 may be treated so as to provide it with positive electric charges by using, for example, an imidazolium salt-based ionic liquid (IS-IL) covalently bonded to the surface of the protection layer.

Although it has been described herein that the graphene layer 321 is synthesized according to a chemical vapor deposition (CVD) method and the synthesized graphene layer is transferred onto the substrate 310, this is exemplary only, and it is also possible to form the graphene layer 321 using other methods. For example, a SIC crystal pyrolysis method, or a fine mechanical method, i.e., a method of attaching a scotch tape to a graphite sample, detaching the attached scotch tape such that the graphene separated from graphite is adsorbed onto the surface of the scotch tape, and transferring the graphene onto the substrate 310, may be used.

Next, as illustrated in FIG. 5F, a nanoparticle layer 331 is formed on the graphene layer 321. An aqueous solution containing a plurality of nanoparticles is prepared to form the nanoparticle layer 331, and the plurality of nanoparticles contained in the aqueous solution may be aligned on the graphene layer by the Langmuir-Blodgett (LB) method. Such a method may be performed by a simple process of putting the substrate 310 having the graphene layer 321 formed thereon into the nanoparticle aqueous solution and then removing the substrate 310 from the nanoparticle aqueous solution.

A exemplary method of forming the nanoparticle layer 331 from gold nanoparticles having a diameter of 5 nm is disclosed herein as follows. 100 mL of 1 mM aqueous HAuCl₄-3H₂O is added in 100 mL of triply deionized water. After adding 10 mL of a 38.8 mM sodium citrate solution into the foregoing resulting solution the solution is stirred for about 5 minutes, and then 10 mL of a 38.8 mM sodium borohydride solution is added into the mixed solution, which is then stirred for about 20 minutes. After dipping the substrate having the graphene layer 321 formed thereon into the above-prepared nanoparticle aqueous solution, the substrate is lifted out of the nanoparticle aqueous solution at a velocity of about 1 mm/min such that the nanoparticles become self-aligned and adsorbed onto the graphene layer 321. As described above, the nanoparticle layer 331 has negative electric charges, since gold particles are cross-linked with each other when self-aligned using the Langmuir-Blodgett (LB) method.

A graphene layer and a nanoparticle layer may additionally be formed on the nanoparticle layer 331 by repeating the foregoing process. For instance, after synthesizing graphene on a substrate S having a metal catalyst layer formed thereon to form a graphene layer 322 as illustrated in FIG. 5G and coating a protection layer P on the graphene layer 322 as illustrated in FIG. 5H, the substrate S having the metal catalyst layer formed thereon is removed to form the structure of FIG. 51. Subsequently, as illustrated in FIG. 5J, the structure of FIG. 5I is transferred onto the nanoparticle layer 331 of FIG. 5F. As illustrated in FIG. 5L, a graphene-nanoparticle structure 300 is manufactured by additionally forming a nanoparticle layer 332 on the graphene layer 322 of FIG. 5K from which the protection layer P has been removed.

The above-mentioned graphene-nanoparticle structure may have high light absorptivity and it is possible to control the wavelength band of light absorption by including a structure in which graphene and zero-dimensional nanoparticles are bonded and formed into a plurality of laminated layers.

The above-mentioned graphene-nanoparticle structures may be applied to photocatalysts, light collection devices, supercapacitors, and other uses because the graphene-nanoparticle structure may enlarge the area exposed to light, may have excellent light absorption properties, and may enable accurate control of the area exposed to light and light absorption properties.

A large area structure is easily realized according to the above-mentioned method of manufacturing a graphene-nanoparticle structure.

As described above, according to the one or more of the above embodiments herein, although a graphene-nanoparticle structure and a method of manufacturing the graphene-nanoparticle structure have been described referring to embodiments illustrated in drawings to help understanding, it should be understood that the exemplary embodiments described therein are descriptive only and do not limit the present disclosure. Descriptions of features or aspects within each embodiment should typically be considered as being available for other similar features or aspects in other embodiments.

What is claimed is:

1. A graphene-nanoparticle structure comprising:
a substrate;
a first graphene layer disposed on the substrate; and
a first nanoparticle layer disposed on the first graphene layer.

2. The graphene-nanoparticle structure of claim 1, further comprising at least one second graphene layer and at least one second nanoparticle layer alternately disposed on the first nanoparticle layer.

3. The graphene-nanoparticle structure of claim 1, wherein the first graphene layer has a positive electric charge.

4. The graphene-nanoparticle structure of claim 2, wherein the first and second graphene layers have a positive electric charge.

5. The graphene-nanoparticle structure of claim 1, wherein the first nanoparticle layer comprises a plurality of nanoparticles comprising metals, metal oxides, semiconductors, or polymers.

6. A photocatalytic structure comprising:
a substrate; and
a photocatalytic layer disposed on the substrate, the photocatalytic layer comprising at least one graphene layer and at least one nanoparticle layer which are alternately disposed.

7. The photocatalytic structure of claim 6, wherein the graphene layer has a positive electric charge.

8. The photocatalytic structure of claim 6, wherein the nanoparticle layer comprises a plurality of nanoparticles configured to have a peak efficiency of optical absorption in a band of visible light.

9. The photocatalytic structure of claim 6, wherein the nanoparticle layer comprises a plurality of gold nanoparticles.

10. A photoelectric device comprising:
a substrate;
a photoactive layer comprising at least one graphene layer and at least one nanoparticle layer alternately disposed on the substrate; and
an electrode unit configured to connect photoelectrically converted electrical energy in the photoactive layer to an external load.

11. A method of manufacturing a graphene-nanoparticle structure, the method comprising:
forming a first graphene layer on a first substrate; and
forming a first nanoparticle layer on the graphene layer.

12. The method of manufacturing the graphene-nanoparticle structure of claim 11, wherein the forming the first graphene layer comprises:
synthesizing graphene on a second substrate having a metal catalyst layer thereon using a chemical vapor deposition method to form a synthesized graphene; and
transferring the synthesized graphene onto the first substrate.

13. The method of manufacturing the graphene-nanoparticle structure of claim 12, wherein the second substrate is a copper foil.

14. The method of manufacturing the graphene-nanoparticle structure of claim 13, further comprising:
coating polymethyl methacrylate (PMMA) on the synthesized graphene; and
removing the copper foil before transferring the synthesized graphene onto the first substrate.

15. The method of manufacturing the graphene-nanoparticle structure of claim 11, wherein the first substrate is a polyethylene terephthalate substrate.

16. The method of manufacturing the graphene-nanoparticle structure of claim 11, further comprising surface treating the first graphene layer to impart positive electric charges thereon.

17. The method of manufacturing the graphene-nanoparticle structure of claim 11, wherein the forming the first nanoparticle layer comprises:
forming an aqueous solution comprising a plurality of nanoparticles; and
aligning the plurality of nanoparticles comprised in the aqueous solution onto the graphene layer using a Langmuir-Blodgett method.

18. The method of manufacturing the graphene-nanoparticle structure of claim 17, wherein the plurality of nanoparticles comprise metals, metal oxides, semiconductors, or polymers.

19. The method of manufacturing the graphene-nanoparticle structure of claim 11, further comprising:
forming a second graphene layer on the first nanoparticle layer; and
forming a second nanoparticle layer on the second graphene layer.

20. The method of manufacturing the graphene-nanoparticle structure of claim 19, wherein the forming the second graphene layer comprises:
synthesizing graphene using a chemical vapor deposition method on a second substrate having a metal catalyst layer formed thereon; and
transferring the synthesized graphene onto the first nanoparticle layer.

21. The method of manufacturing the graphene-nanoparticle structure of claim 20, further comprising surface treating the second graphene layer to impart positive electric charges thereon.
